(19) United States
(12) Patent Application Publication
(10) Pub. No.: US 2007/0200174 A1
(43) Pub. Date: Aug. 30, 2007

(54) SOI substrate, mask blank for charged particle beam exposure, and mask for charged particle beam exposure

(75) Inventors: Kenichi Morimoto, Tokyo (JP); Yuki Aritsuka, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: DAI NIPPON PRINTING CO., LTD.

(21) Appl. No.: 11/514,890

(22) Filed: Sep. 5, 2006

(30) Foreign Application Priority Data
Sep. 2, 2005 (JP) 2005-254758

(51) Int. Cl. H01L 27/12

(52) U.S. Cl. 257/347

(57) ABSTRACT

The invention provides an SOI substrate 10 comprising on one major surface of a silicon single crystal 13 a silicon thin-film layer 11 via a buried silicon oxide film 12, characterized in that a substrate warp preventive layer 14 is provided on another major surface of the silicon single crystal 13. The invention also provides a charged particle beam exposure mask blank and a charged particle beam exposure mask having high mask pattern alignment precision, each using that SOI substrate. The invention has the advantages of being easy to fabricate, and capable of preventing a warp in the substrate.

### BACKGROUND OF THE INVENTION

The present invention relates generally to an SOI (silicon on insulator) substrate used for the fabrication of semiconductor devices, etc. and a lithography mask blank and mask using the same, and more particularly to a charged particle beam exposure mask blank for the preparation of a mask that is used for transfer of a mask pattern onto a wafer using charged particle beams such as electron beams and ion beams in electron-beam projection lithography (EPL for short), low energy electron-beam proximity projection lithography (LEEPL for short), etc., and that mask.

As the definition and integration of devices in semiconductor integrated circuits grow high, electron beam transfer lithography techniques developed for transferring the desired shapes onto wafers using charged particle beams, especially electron beams, for instance, the EPL or LEEPL methods are now superceding prior art photo-lithography techniques harnessing light. Typically for the EPL method as the electron beam transfer lithography technique, there is a system developed (for instance, see patent publication 1), wherein a mask pattern is divided into small areas, an electron beam is directed to each small area using a stencil mask having a through-hole pattern that is located at that small area with given size and arrangement to transfer the electron beam formed through that through-hole pattern onto a wafer that is that substrate to be exposed, and a device pattern is formed while linking together given patterns divisionally formed on a mask on the substrate to be exposed.

The mask for use with the EPL method, for instance, is provided with a through-hole pattern on a silicon thin film. The area of that pattern is reinforced with silicon or other posts. Such a structure ensures that a deflection of the pattern area is held back, resulting in an improvement in pattern alignment precision.

For mask substrates, an SOI substrate having a structure having a silicon oxide film (called as a BOX (buried oxide) layer) between a silicon thin film and a silicon single crystal is mainly used. The SOI substrate has already successfully been used as the one for semiconductor devices with high reliability quality. The SOI substrate is of such a structure that two silicon substrates are laminated together with a silicon oxide film interleaved between them. A support silicon that provides a support portion for a mask blank or mask is a few hundred μm in thickness, and the silicon thin-film layer to be provided with a mask pattern has a thickness of a few μm. The silicon oxide film that is the BOX layer functions as an etching stopper layer at the time of mask blank fabrication or mask fabrication.

A problem with the use of the SOI substrate is stress remaining in the mask. That is, when there is stress remaining in the mask after mask pattern formation, the mask warps and pattern alignment precision becomes worse. For improvements in mask pattern alignment precision, it is thus necessary to keep the substrate against warping.

A chief cause of the warping of the SOI substrate is compression stress due to the intermediate silicon oxide film. And then, that oxide film is usually formed by thermal oxidation of a silicon wafer. Given a film having the same thickness and the same nature, it is supposed to have the same stress; it has been known that the same thermally oxidized film as the intermediate silicon oxide film is formed as a substrate warp preventive layer on the back face of the SOI substrate, too, and that back-face oxide film is allowed to remain until the final mask form, as proposed typically by patent publication 2. Further, there has been a transfer mask known (see patent publication 3), wherein a warp regulation film such as a silicon nitride film is further formed on the back-face oxide film.

Patent Publication 1: U.S. Pat. No. 2,829,942

Patent Publication 2: JP-A-2002-151385

Patent Publication 3: JP-A-2004-111828

With the SOI substrate wherein the thermally oxidized film identical in nature to the intermediate silicon oxide layer (BOX layer) is formed on the back face of the SOI substrate, too, such as the one set forth in patent publication 2, however, there is a problem that even when the oxide film identical in nature to the BOX layer is provided on the back face of the substrate, it does not satisfactorily function, as a warp preventive layer, thanks to the presence of the silicon thin-film layer on the BOX layer. To avoid this problem, there has been a mask proposed, wherein the warp regulation layer is further provided on the back-face oxide film, as set forth in patent publication 3. However, this ends up with another problem that the fabrication process becomes a lot more awkward.

The mask set forth in patent publications 2 and 3 requires a mask fabrication process step for preventing the back-face thermally oxidized film formed of the same material as that BOX layer from being removed simultaneously with the etching-off of the BOX layer, resulting in a problem that the mask fabrication process becomes a lot more awkward. Further, the back-face thermally oxide film, because of being an insulating film, requires that an electrically conductive film be laminated and formed on the thermally oxidized film for the antistatic purpose of the mask.

### SUMMARY OF THE INVENTION

In view of such problems with the prior art as mentioned above, it is an object of the present invention to provide an SOI substrate that is easy to fabricate and devoid of warping, a charged particle beam exposure mask blank using that SOI substrate, and a charged particle beam exposure mask ensuring high mask pattern alignment precision.

To achieve the above object, the invention of claim 1 is directed to an SOI substrate, comprising on one major surface of a silicon single crystal a silicon thin-film layer via a buried silicon oxide film, characterized in that a substrate warp preventive layer comprising silicon is provided on another major surface of said silicon single crystal.

The SOI substrate according to the invention of claim 2 is characterized in that in the SOI substrate of claim 1, the silicon of said substrate warp preventive layer is in an amorphous state.

The SOI substrate according to the invention of claim 3 is characterized in that in the SOI substrate of claim 1 or 2, said substrate warp preventive layer comprising silicon has been formed by a sputtering technique.

The SOI substrate according to the invention of claim 4 is characterized in that in the SOI substrate of any one of claims 1-3, said substrate warp preventive layer comprising silicon includes one or more of metals selected from the group consisting of Ta, Cr, Ti, Mo, W and Zr.

The SOI substrate according to the invention of claim 5 is characterized in that in the SOI substrate of any one of claims 1-3, a metal thin film formed of one of metals selected from the group consisting of Ta, Cr, Ti, Mo, W and Zr is laminated on said substrate warp preventive layer comprising silicon.

The invention according to claim 6 is directed to a charged particle beam exposure mask blank, characterized in that the SOI substrate of any one of claim 1-4 is used, and portions of said substrate warp preventive layer and said silicon single crystal that provide an exposure area are removed off to form an opening.

The charged particle beam exposure mask blank according to the invention of claim 7 is characterized in that the SOI substrate of claim 5 is used, and portions of said metal thin film, said substrate warp preventive layer and said silicon single crystal that provide an exposure area are removed off to form an opening.

The charged particle beam exposure mask according to the invention of claim 8 is characterized in that the SOI substrate of any one of claims 1-4 is used, a mask pattern is formed on the silicon thin-film layer on one major surface side of said SOI substrate, and portions of said substrate warp preventive layer, said silicon single crystal and said buried silicon oxide film that provide an exposure area on another major surface are removed off to form an opening.

The invention according to claim 9 is directed to a charged particle exposure mask, characterized in that the SOI substrate of claim 5 is used, a mask pattern is formed on the silicon thin-film layer on one major surface side of said SOI substrate, and portions of said metal thin film, said substrate warp preventive layer, said silicon single crystal and said buried silicon oxide film that provide an exposure area on another major surface are removed off to form an opening.

In view of the fact that stress control of the thin film formed on the substrate can be implemented by adjustment of film-formation conditions, the present invention ensures that by forming a silicon film of the same material as that of the substrate under optimized conditions, both the effect on prevention of a warp in the substrate and the effect on cutting back the subsequent substrate processing step are achievable.

According to the present invention wherein the silicon thin film is formed under the optimized film-formation conditions as the substrate warp preventive layer to be provided on another major surface (the back face side) of the SOI substrate, stress adjustment of the substrate, viz., adjustment of the quantity of warping of the substrate can be implemented so that an SOI substrate can be obtained with its warping held back.

The use of the SOI substrate according to the present invention makes sure of a charged particle beam exposure mask blank capable of obtaining a mask with high pattern alignment precision and a charged particle beam exposure mask having high mask pattern alignment precision.

When the SOI substrate according to the present invention is used for the fabrication of a charged particle beam exposure mask, the step of removing off a portion of the mask corresponding to an exposure area (viz., the etching step for the substrate warp preventive layer and silicon single crystal) that is one mask fabrication process step can be implemented in one single operation, because the substrate warp preventive layer to be formed on another major surface (back face side) of the substrate is the same silicon material as that of the substrate, thereby enabling the mask fabrication process to be cut back. Further, if an electrically conductive metal such as Ta is incorporated in the warp preventive layer at the time of forming a silicon film by sputtering on the back face of the substrate, it is then possible to form a silicon thin film that is also of electrical conductivity and, hence, obtain a mask having an antistatic effect.

Still other objects and advantages of the invention will be in part obvious and will in part be apparent from the specification.

The invention accordingly comprises the features of construction, combinations of elements, and arrangement of parts which will be exemplified in the construction hereinafter set forth, and the scope of the invention will be indicated in the claims.

### BRIEF DESCRIPTION OF THE DRAWINGS

FIG. 1 is schematically illustrative in section of one embodiment of the SOI substrate according to the present invention.

FIG. 2 is schematically illustrative in section of the inventive charged particle beam exposure mask blank fabricated with the use of the SOI substrate depicted in FIG. 1.

FIG. 3 is schematically illustrative in section of the inventive charged particle beam exposure mask fabricated with the use of the SOI substrate depicted in FIG. 1.

FIG. 4 is schematically illustrative in section of the steps of fabricating the inventive SOI substrate, and fabricating the inventive charged particle beam exposure mask with the inventive SOI substrate.

FIG. 5 is representative of argon gas pressure (Pa) vs. internal stress (MPa) relations of the formed silicon thin film at the time of sputtering of silicon.

FIG. 6 is illustrative of the basic definition of a “warp” in a wafer substrate.

FIG. 7 is illustrative of how to measure the warping of the SOI substrate while it is horizontally placed on three support points.

FIG. 8 is illustrative of how to correct deflection of the SOI substrate by gravity in the case where it is horizontally placed on three support points.

FIG. 9 is a top view illustrative of the results of a three-point support measurement of the SOI substrate prior to forming the substrate warp preventive layer on it.

FIG. 10 is illustrative of height maps for the SOI substrate prior to forming the substrate warp preventive layer on it: FIG. 10(a) is for the front face side and FIG. 10(b) is for the back face side.

FIG. 11 is a top view illustrative of the results of a three-point support measurement of the SOI substrate after the substrate warp preventive layer is formed on it.

FIG. 12 is illustrative of height maps for the SOI substrate after the substrate warp preventive layer is formed on it: FIG. 12(a) is for the front face side and FIG. 12(b) is for the back face side.

### DESCRIPTION OF THE PREFERRED EMBODIMENTS

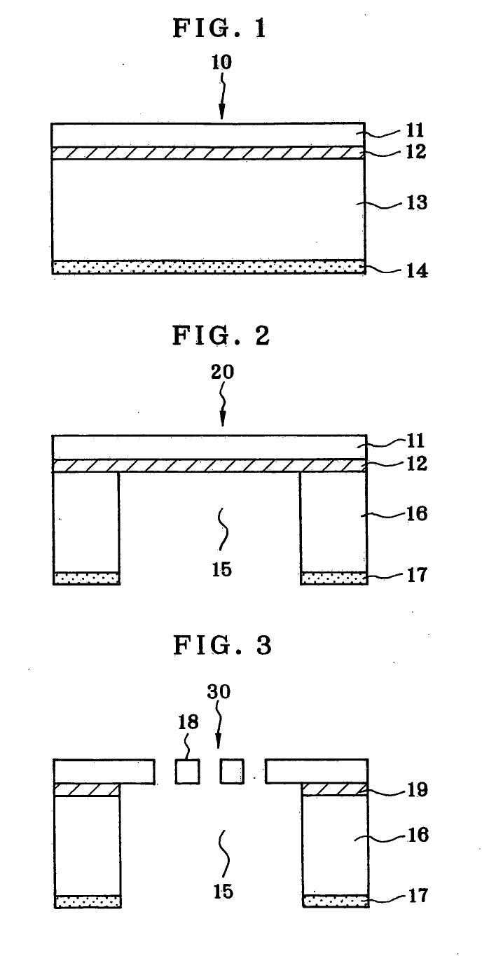

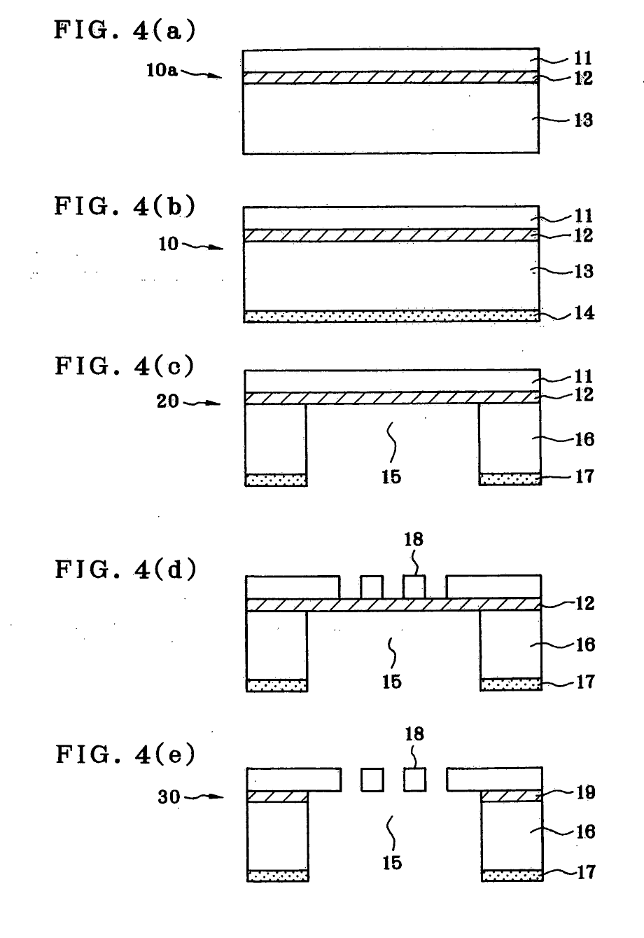

Several embodiments of the present invention are now explained with reference to the accompanying drawings. FIG. 1 is schematically illustrative in section of the SOI substrate according to the present invention; FIG. 2 is schematically illustrative in section of the inventive charged particle beam exposure mask blank fabricated with the use of the SOI substrate depicted in FIG. 1; FIG. 3 is schematically illustrative in section of the inventive charged particle beam exposure mask fabricated with the use of the charged particle beam exposure mask blank depicted in FIG. 2; and FIG. 4 is schematically illustrative in section of the steps of fabricating the inventive SOI substrate, and fabricating the inventive charged particle beam exposure mask with the use of the inventive SOI substrate. Throughout FIGS. 1-4, like numerals indicate like components.

Referring first to FIG. 4, an SOI substrate 10a that is an SOI substrate precursor of the present invention is provided, as depicted in FIG. 4(a). For the SOI substrate 10a here that is a material before the substrate warp preventive layer is formed on the back face, use may be made of various SOI substrates, each including on one major surface of a silicon single crystal 13 (herein also called the “front face”) a silicon thin film via a buried silicon oxide layer 12, for instance, a substrate wherein a buried silicon oxide film is formed by thermal oxidization on a silicon single crystal wafer and another silicon single crystal wafer is laminated onto that, followed by polishing of the whole assembly, an ELTRAN® (registered mark)(epitaxial layer transfer) substrate using epitaxial silicon, or a SIMOX (separation by implanted oxygen) substrate formed by oxygen ion injection. There is no particular limitation to the thickness of each component of the SOI substrate 10a; however, when it is used for the charged particle beam exposure mask, the silicon single crystal 13 has a thickness of 500 to 725 μm, the intermediate silicon oxide layer 13 has a thickness of about 0.1 to 1.0 μm, and the front-face silicon thin film 12 has a thickness of 0.2 μm to a few μm. The above values inclusive of SOI substrate size vary with lithography systems and the mask form used.

### SOI Substrate of the Invention

Then, the SOI substrate 10a is washed and dried, after which, as depicted in FIG. 4(b), a substrate warp preventive layer 14 comprising silicon is formed on another major surface (herein also called the back face) of the SOI substrate to form the inventive SOI substrate 10. The substrate warp preventive layer 14 is preferably formed by vacuum film-formation techniques like a sputtering technique or a vacuum vapor deposition technique, although the sputtering technique is more preferable, because it is easier to control the stress of the silicon thin film, and because of being better capable of forming a film of high quality. Note here that the force of reducing the warping of the substrate is proportional to the product of the stress and thickness of the thin film.

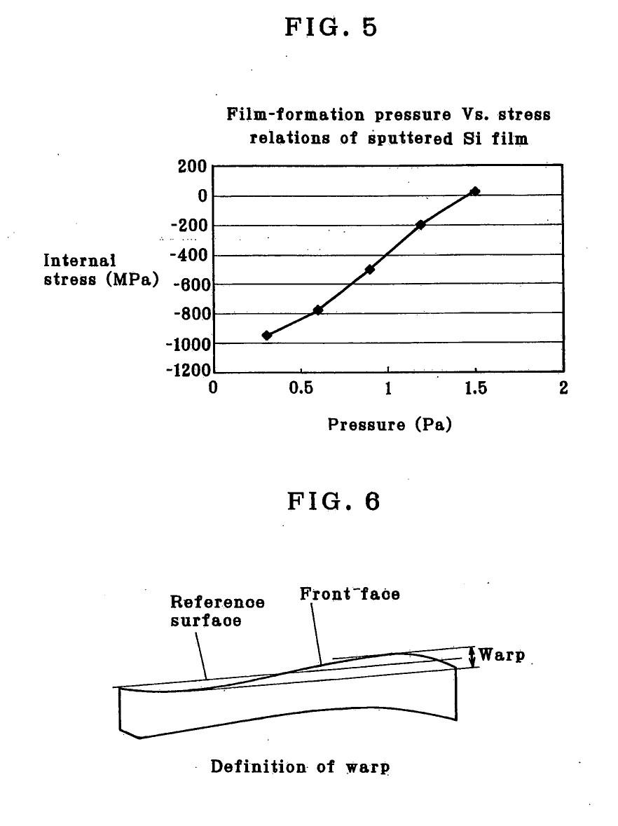

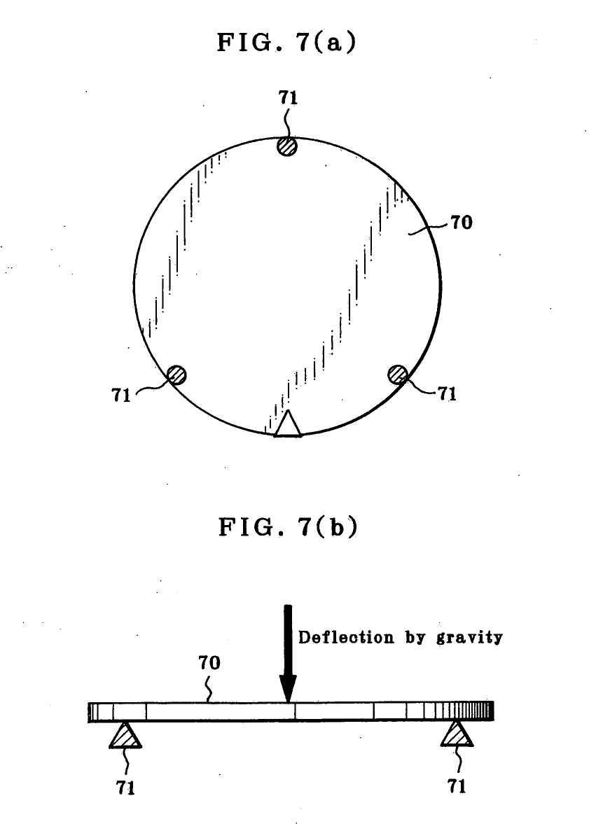

As an example, FIG. 5 is illustrative of argon gas pressure (Pa) vs. internal stress (MPa) relations of the silicon thin film obtained here at the time of sputtering of silicon. As can be seen from FIG. 5, the internal stress of the silicon thin film can have a positive or negative value about zero with changes in the argon gas pressure (Pa), so that tensile stress and compression stress can be set at the desired values depending on the film-formation conditions. In other words, the quantity of warping of the SOI substrate can be adjusted with the stress and thickness of the formed silicon thin film, and the internal stress of the silicon thin film can be controlled by the pressure at the time of film formation by sputtering. And then, the thickness of the silicon thin film can be controlled by the film-formation-by-sputtering time.

FIG. 1 is schematically illustrative in section of the inventive SOI substrate 10 obtained as described above. In the present invention, the silicon thin film that forms the substrate warp preventive layer 14 has a thickness of about 0.1 μm to a few μm, from which a proper one is determined in consideration of relations to the internal stress of the silicon thin film. As the thickness of the silicon thin film is less than 0.1 μm, it is less effective on warp prevention, and a thickness exceeding a few μm is not preferable for substrate fabrication, because much time is taken for sputtering.

Further, the silicon thin film that forms the warp preventive layer 14 of the inventive SOI substrate 10 is formed by vacuum film-formation techniques like a sputtering technique, showing an amorphous state.

Furthermore, the substrate warp preventive layer 14 of the inventive SOI substrate 10 that comprises silicon may include one or more of the electrically conductive metals selected from the group consisting of Ta, Cr, Ti, Mo, W and Zr. By incorporating the electrically conductive metal or metals in the silicon thin film that forms the substrate warp preventive layer 14, it is possible to impart electrical conductivity to the substrate warp preventive layer 14. This in turn facilitates fabrication of a high-precision mask having an antistatic function, etc. upon mask pattern transfer by charged particle beams (especially the LEEPL process).

Imparting electrical conductivity to the substrate warp preventive layer 14 may also be achievable by lamination on the substrate warp preventive layer 14 comprising silicon of a metal thin film of any one of the metals selected from the group consisting of Ta, Cr, Ti, Mo, W and Zr.

### Charged Particle Beam Exposure Mask Blank

Then, a photoresist and like other material are coated on the substrate warp preventive layer 14, an opening pattern is formed by a photolithographic technique, and the substrate warp preventive layer 14 and then the silicon single crystal 13 is etched out from the back face side of the substrate with the buried silicon oxide film 12 used as an etching stopper layer to form an opening 15. Afterwards, the photoresist and so on are peeled off to form a mask blank 20 as depicted in FIG. 4(c). The etching of the substrate warp preventive layer 14 and silicon single crystal 13 may be implemented either by a wet etching technique using a known KOH aqueous solution or by a dry etching technique using a fluorine-base gas such as SF₆, and CF₄.

FIG. 2 is schematically illustrative in section of the inventive charged particle beam exposure mask blank 20 obtained as described above. In FIG. 2, portions of the substrate warp preventive layer 14 and the silicon single crystal 13 corresponding to the opening 15 in the mask are etched out, and unetched portions 17 and 16 of the substrate warp preventive layer and the silicon single crystal remain as a support, causing the intermediate silicon oxide layer 12 to be exposed in the opening 15 on the back face side of the substrate.

### Charged Particle Beam Exposure Mask

Then, an electron beam resist or like other material is coated on the silicon thin-film layer 11 on the front face side of the substrate, and a given pattern is formed on that by an electron beam lithography system or the like, followed by development. The thus exposed silicon thin-film layer 11 is dry etched to provide electron beam through-holes using the buried silicon oxide layer 12 as an etching stopper layer, thereby forming a mask pattern 18 on the buried silicon oxide layer 12, as depicted in FIG. 4(d).

Then, the buried silicon oxide layer 12 that functions as the etching stopper layer for the opening 15 is etched off using buffer fluoric acid or the like to form a charged particle beam exposure mask 30, as depicted in FIG. 4(e).

FIG. 3 is schematically illustrative in section of the inventive charged particle beam exposure mask 30 obtained as described above, wherein using the silicon single crystal 16 as a support carrier, there is the mask pattern 18 provided via a buried silicon oxide film 19. In FIG. 3, the mask is prevented from warping by the substrate warp preventive layer 17 so that a mask having high flatness and good pattern alignment precision can be obtained.

### EXAMPLE

The present invention is now explained in further details with reference to examples.

### Example 1

### SOI Substrate

For the material of the inventive SOI substrate, provision was made of a 200 mm diameter SOI substrate having a 725 μm thick silicon single crystal, a 1 μm thick intermediate buried silicon oxide film and a 2 μm thick front-face silicon thin-film layer. This substrate is a mask SOI substrate of general specifications, available in the form of commercial products.

The “warp” in the SOI or other wafer substrate here is in principle defined as a “difference between the maximum and the minimum value of the distance between the front face of the wafer and the best fit reference plane of the surface of the wafer worked out by the method of least square in a weightless state and a state where the wafer is not fixed by adsorption”, as in FIG. 6 that defines that warp. However, there is much difficulty in creating the “weightless state” and the “state where the wafer is not fixed by adsorption”. In the present invention, therefore, the warp was measured while an SOI substrate 70 was horizontally placed on three support points 71. However, when the warp is measured while a wafer such as an SOI substrate is horizontally placed on three support points, it is necessary to correct measurements for deflection of the SOI substrate 70 by gravity.

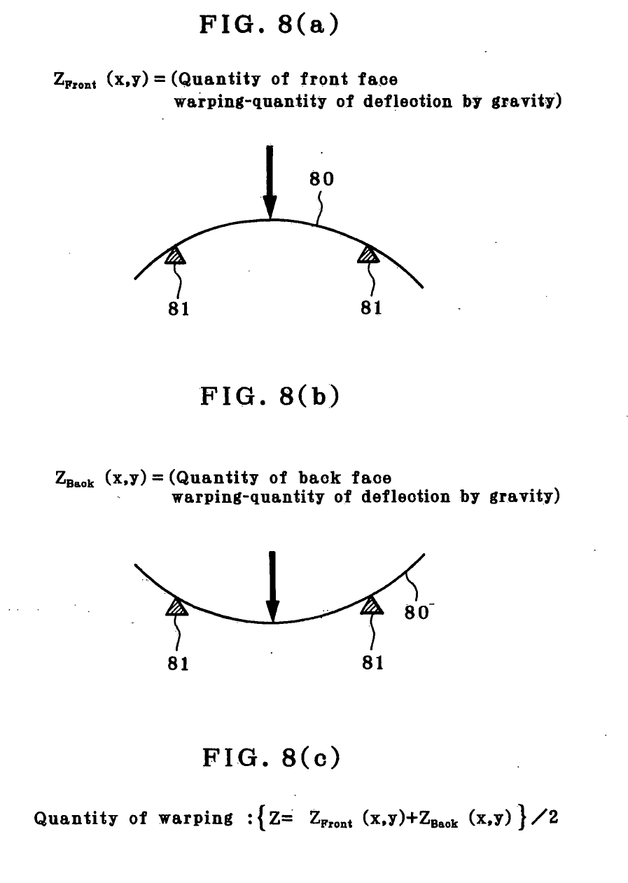

In the present invention, therefore, height maps (three-dimensional data on the height of an SOI substrate on the X coordinates, and the Y coordinates, respectively) for both the front and the back face side of an SOI substrate 80 horizontally placed on three support points are obtained, as depicted in FIGS. 8(a) and 8(b). Front face side height Z_{Front} (x, y) and back face side height Z_{Back} (x, y) are found from the following equations:
Z_{Front}(x,y)=(Quantity of Front Face Warping)−(Quantity of Deflection by Gravity)
Z_{Back}(x,y)=(Quantity of Back Face Warping)−(Quantity of Deflection by Gravity)

Then, as represented by the following equation (1) (FIG. 8(c)), the heights of the SOI substrate on the X, and Y coordinates on the front and the back face side are summed up and divided by 2 to erase off the deflection of the SOI substrate due to gravity. This way the quantity of warping, Z, of the SOI substrate could be obtained.
Z=[Z_{Front}(x,y)+Z_{Back}(x,y)]/2 (1)

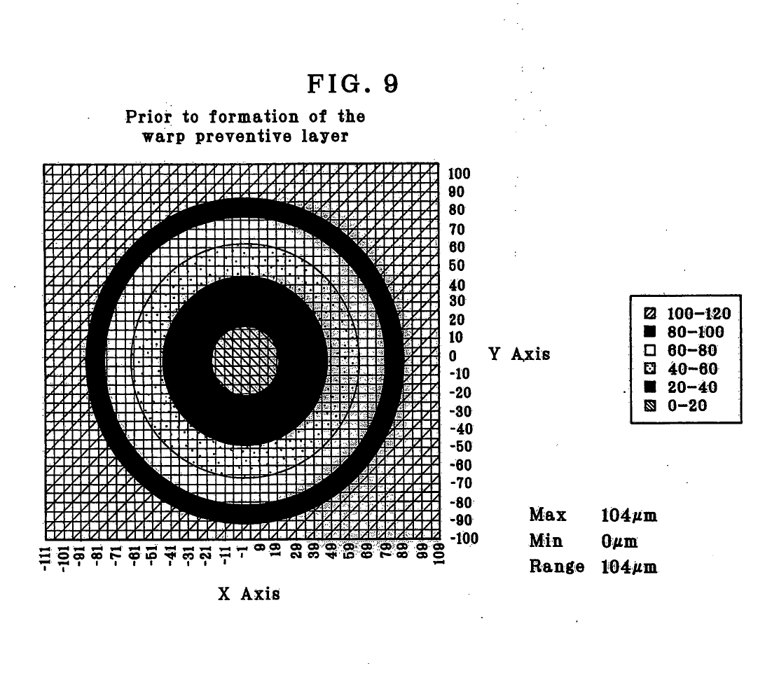

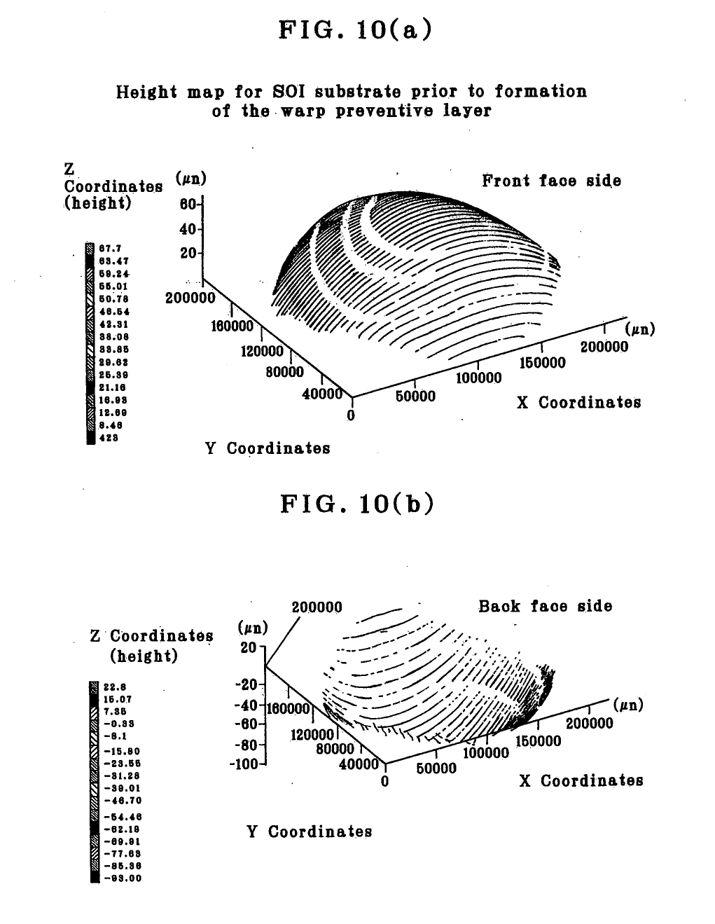

First of all, the quantity of warping of the SOI substrate used as the material in this example, prior to formation of the substrate warp preventive layer, was in advance measured, using a commercially available stage scan type laser probe three-dimensional measuring unit. FIG. 9 is a top view illustrative of the results of the three-point support measurement of the SOI substrate prior to forming the substrate warp preventive layer on it. FIGS. 10(a) and 10(b) are map representations three-dimensionally indicative of height maps on the front and the back face side of the SIO substrate, respectively. In the instant example, the quantity of warping of the SOI substrate prior to formation of the substrate warp preventive layer was 104 μm.

Then, to prevent the warping of the SOI substrate by stress regulation, a silicon thin film was formed as the substrate warp preventive layer on the back face of the SOI substrate by means of a sputtering technique using a silicon target in an argon gas atmosphere.

As already stated, the force of preventing the warping of the SOI substrate is proportional to the product of the stress of the silicon thin film formed by a sputtering technique and the thickness of that silicon thin film; in other words, the quantity of warping of the substrate can be regulated by the stress and thickness of the silicon thin film, and the internal stress of the silicon thin film can be controlled with pressure at the time of sputtering film formation.

In this example, the sputtering system was used at an output of 5 kW and an argon gas pressure of 0.6 Pa for 100 seconds to form a 0.3 μm thick silicon thin film, thereby forming a substrate warp preventive layer.

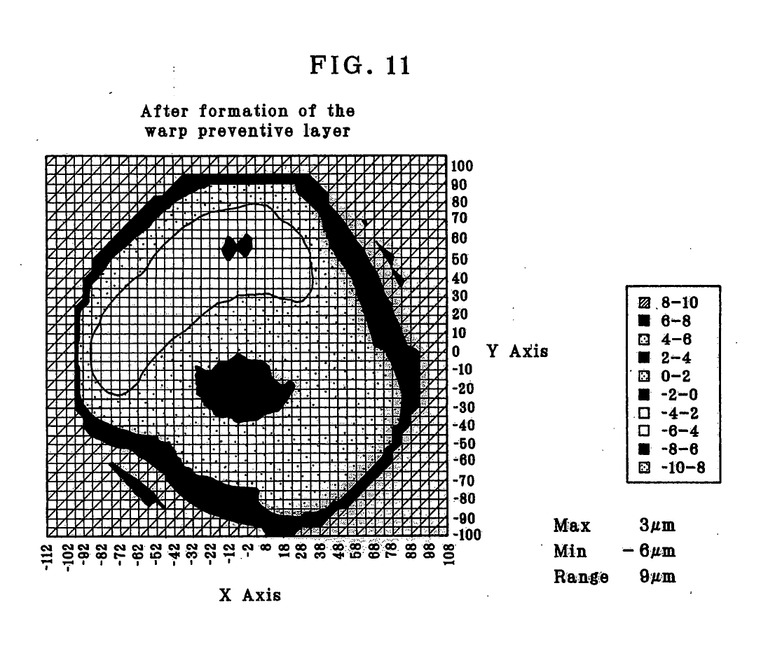

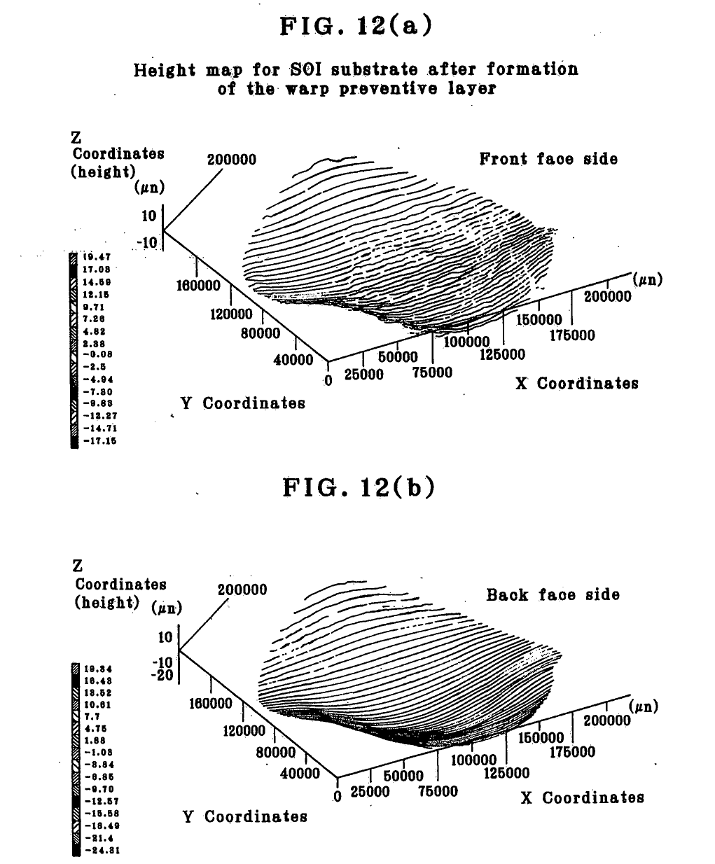

FIG. 11 is a top view illustrative of the results of the three-point support measurement of the SOI substrate after the substrate warp preventive layer is provided on it. FIGS. 12(a) and 12(b) are map representations three-dimensionally indicative of height maps on the front and the back face side of the SOI substrate, respectively. In the instant embodiment, the quantity of warping of the SOI substrate after the formation of the substrate warp preventive layer was 9 μm.

By providing the back face side of the SOI substrate of this example with the silicon thin film as the substrate warp preventive layer as described above, the quantity of warping of the substrate could be reduced from an initial 109 μm down to 9 μm; an SOI substrate of good flatness and high quality yet with minimized warping could be obtained.

### Charged Particle Beam Exposure Mask Blank

Next, there was a 200 mm diameter SOI substrate provided, having the above 0.3 μm thick silicon thin film as the substrate warp preventive layer. Then, a photo-resist using a novolac resin was coated at a thickness of 15 μm on the substrate warp preventive layer, exposed to light using a photomask having an opening pattern, and developed to form a given resist pattern. The opening pattern comprised a plurality of opening units, each being 1.13×1.13 mm, with a width between openings providing a silicon single crystal support being 170 μm.

Subsequently, on the basis of the above resist pattern, a Bosch process with alternately supplied SF₆ gas and C₄F₈ gas was used on an inductively coupled plasma-reactive ion etching system to dry etch the substrate warp preventive layer and the silicon single crystal in this order, thereby forming openings in a portion corresponding to a mask exposure area while the intermediate buried silicon oxide film was used as an etching stopper layer. Thereafter, the resist was stripped off using a dedicated stripping solution to obtain a charged particle beam exposure mask blank.

### Charged Particle Beam Exposure Mask

Next, an electron beam resist was coated on the silicon thin-film layer on the front face of the above mask blank, and a given pattern was rendered on it with a mask-dedicated electron beam lithography system and developed to form a 260 nm line-and-space resist pattern. Thereafter, the silicon thin-film layer was dry etched using an HBr gas while the resist pattern was used as an etching mask to form on the intermediate buried silicon oxide film a silicon thin-film layer mask pattern having electron beam through-holes.

Then, the buried silicon oxide film exposed in the openings was etched off using buffer fluoric acid (fluoric acid:ammonium fluoride=1:10) so that there could be a charged particle beam exposure mask obtained, having a 260 nm line-and-space mask pattern having electron beam through-holes.

In the charged particle beam exposure mask according to this example, the opening size on the back face of the mask was 1.13×1.13 mm, the support silicon was of 170 μm in width and 725 μm in height, and the front mask pattern comprising the silicon thin film was of 2 μm in thickness and 260 nm in line-and-space. The warping of the substrate was minimized to 9 μm due to the presence of the 0.3 μm thick substrate warp preventive layer on its back face. Thus, there could be a mask obtained, having high substrate flatness and high pattern alignment precision.

### Example 2

A 200 mm diameter SOI substrate having the same specifications as in Example 1 was provided as the SOI substrate material here. The quantity of warping of the substrate was 95 μm, as measured by the three-point support method.

Then, a Ta silicide target was prepared. Using this target, a Ta-containing silicon thin film was formed on the back face of the SOI substrate in an argon gas atmosphere by means of a sputtering technique, thereby obtaining a substrate warp preventive layer, after which the quantity of warping of the substrate was found to be reduced down to 7 μm.

In the SOI substrate of this example, the substrate warp preventive layer on its back face was of electrical conductivity; by use of that SOI substrate, there could be a charged particle beam exposure mask prepared, having high antistatic effects and high pattern alignment precision.

### Example 3

A 200 mm diameter SOI substrate having the same specifications as in Example 1 was provided as the SOI substrate material here. The quantity of warping of the substrate was 90 μm, as measured by the three-point support method.

Then, using a silicon target, silicon was sputtered onto the back face of the SOI substrate by means of a sputtering technique in an argon gas atmosphere. Subsequently, using a Ta target, Ta was sputtered to form a substrate warp preventive layer comprising a silicon thin film and a Ta thin film. The quantity of warping of the substrate was 8 μm, as measured after the provision of the substrate warp preventive layer.

Using this SOI substrate, the substrate warp preventive layer on the back face was etched in order of Ta and silicon to form openings. It was thus possible to prepare a charged particle beam exposure mask having high antistatic effects and high pattern alignment precision.

While the SOI substrate of the present invention is well fit for use for charged particle beam exposure mask blanks and charged particle beam exposure masks, it is also suitable for semiconductor devices that are one of main purposes of SOI substrates, because of being prevented from warping and having high flatness. The SOI substrate of the present invention comprising the substrate warp preventive layer defined by a silicon thin film, because of being higher in substrate surface's flatness than prior art SOI substrates, ensures that there can be high alignment precision obtained at each lithography step of semiconductor device fabrication and, hence, a resist pattern of high quality in terms of both side and alignment can be formed. It is thus possible to fabricate devices of much higher definition and quality.

What we claim is:

1. An SOI substrate, comprising on one major surface of a silicon single crystal a silicon thin-film layer via a buried silicon oxide film, characterized in that a substrate warp preventive layer comprising silicon is provided on another major surface of said silicon single crystal.

2. The SOI substrate according to claim 1, characterized in that the silicon of said substrate warp preventive layer is in an amorphous state.

3. The SOI substrate according to claim 1 or 2, characterized in that said substrate warp preventive layer comprising silicon has been formed by a sputtering technique.

4. The SOI substrate according to any one of claims 1-3, characterized in that said substrate warp preventive layer comprising silicon includes one or more of metals selected from the group consisting of Ta, Cr, Ti, Mo, W and Zr.

5. The SOI substrate according to any one of claims 1-3, characterized in that a metal thin film formed of one of metals selected from the group consisting of Ta, Cr, Ti, Mo, W and Zr is laminated on said substrate warp preventive layer comprising silicon.

6. A charged particle beam exposure mask blank, characterized in that the SOI substrate of any one according to claim 1-4 is used, and portions of said substrate warp preventive layer and said silicon single crystal that provide an exposure area are removed off to form an opening.

7. A charged particle beam exposure mask blank, characterized in that the SOI substrate according to claim 5 is used, and portions of said metal thin film, said substrate warp preventive layer and said silicon single crystal that provide an exposure area are removed off to form an opening.

8. A charged particle beam exposure mask, characterized in that the SOI substrate according to any one of claims 1-4 is used, a mask pattern is formed on the silicon thin-film layer on one major surface side of said SOI substrate, and portions of said substrate warp preventive layer, said silicon single crystal and said buried silicon oxide film that provide an exposure area on another major surface are removed off to form an opening.

9. A charged particle exposure mask, characterized in that the SOI substrate according to claim 5 is used, a mask pattern is formed on the silicon thin-film layer on one major surface side of said SOI substrate, and portions of said metal thin film, said substrate warp preventive layer, said silicon single crystal and said buried silicon oxide film that provide an exposure area on another major surface are removed off to form an opening.
